(19) United States
(12) Patent Application Publication
(10) Pub. No.: US 2024/0282646 A1
(43) Pub. Date: Aug. 22, 2024

(54) METHOD FOR MEASURING THICKNESS OF SILICON EPITAXIAL LAYER

(71) Applicant: Shanghai Huali Integrated Circuit Corporation, Shanghai (CN)

(72) Inventors: Jiaqi HONG, Shanghai (CN); Jun TAN, Shanghai (CN); Qiang YAN, Shanghai (CN)

(21) Appl. No.: 18/465,011

(22) Filed: Sep. 11, 2023

(30) Foreign Application Priority Data
Feb. 21, 2023 (CN) 202310150318.7

(51) Int. Cl. H01L 21/66; C30B 25/16; C30B 25/18; C30B 29/06; C30B 29/52; C30B 29/68; G01B 11/06; H01L 21/02

(52) U.S. Cl. CPC H01L 22/26; C30B 25/16; C30B 25/186; C30B 29/06; C30B 29/52; C30B 29/68; G01B 11/06; H01L 21/02057; H01L 21/0245; H01L 21/02502; H01L 21/02532

(57) ABSTRACT

The present application discloses a method for measuring thickness of a silicon epitaxial layer, including: step 1: performing epitaxial growth to grow a first semiconductor material layer made of a material optically distinguishable from a silicon layer on a surface of a first wafer composed of a first silicon substrate; step 2: performing epitaxial growth to grow a first silicon epitaxial layer; step 3: measuring the thickness of silicon to obtain the first thickness of the first silicon epitaxial layer; step 4: performing epitaxial growth on a surface of the first silicon epitaxial layer to form a second silicon epitaxial layer; step 5: measuring the thickness of silicon to obtain the superposed thickness of the first silicon epitaxial layer and the second silicon epitaxial layer, and subtracting the first thickness from the superposed thickness to obtain the thickness of the silicon epitaxial layer.

### CROSS-REFERENCES TO RELATED APPLICATIONS

This application claims the priority to Chinese patent application No. 202310150318.7 filed on Feb. 21, 2023, and entitled “METHOD FOR MEASURING THICKNESS OF SILICON EPITAXIAL LAYER”, the disclosure of which is incorporated herein by reference in entirety.

### TECHNICAL FIELD

The present application relates to a method for manufacturing a semiconductor integrated circuit, in particular to a method for measuring thickness of a silicon epitaxial layer.

### BACKGROUND

Steep Retrograde Well (SRW) is produced by using the process of well implantation and silicon epitaxy. SRW can achieve device performance boost. Wells are formed in a surface area of a silicon substrate (sub Si), while epitaxial Si is formed on the silicon substrate. The epitaxial Si will subsequently become channel regions of NMOS/PMOS, so its thickness and uniformity are crucial. However, since a epitaxial Si layer is not optically distinguishable from sub Si, the thickness cannot be directly measured.

Referring to FIGS. 1A-1C, which illustrate schematic diagrams of device structures obtained in each step of an existing process for forming an SRW. The existing process for forming the SRW includes the following steps:

Referring to FIG. 1A, providing a silicon substrate and performing ion implantation in the well as illustrated by backingarrows 102 to form a steep retrograde well 101 in the silicon substrate. The steep retrograde well 101 is formed in all of the silicon substrate, but only a section of it is illustrated in FIG. 1A as an example.

Referring to FIG. 1B, performing epitaxial growth to form a silicon epitaxial layer 1031 on a surface of the silicon substrate. Typically, the silicon epitaxial layer 1031 adopts a non-doped structure.

Referring to FIG. 1C, performing patterning etching on the silicon epitaxial layer 1031 to form fins 103.

Forming shallow trench isolation 104 at two sides of the fins 103.

Then, forming gate structures. The gate structures are disposed top surfaces and side surfaces of the fins 103. Source-drain regions are formed in the fins 103 on two sides of the gate structures.

The fins 103 disposed under the gate structures form channel regions. Since the silicon epitaxial layer 1031 adopts the non-doped structure, the SRW process can prevent the formation of high well doping into the channel regions, thus the gate structures provide strong control ability over the channel regions.

Since both the silicon epitaxial layer 1031 and the silicon substrate are made of silicon and are not optically distinguishable from each other, the thickness of the silicon epitaxial layer 1031 cannot be directly measured by optical techniques.

Referring to FIG. 2, which illustrates a schematic structural diagram of a device obtained in an existing first method for measuring thickness of a silicon epitaxial layer. The existing first method for measuring the thickness of the silicon epitaxial layer includes the following steps:

Performing epitaxial growth in a Si epitaxy equipment with a germanium (Ge) source to sequentially grow a SiGe epitaxial layer 202 and a Si epitaxial layer 203 on the surface of a silicon substrate 201. Because the characteristic that a layer of SiGe material is optically distinguishable from a Si material, the thickness of the Si epitaxial layer 203 is measured by using the SiGe epitaxial layer 202 as a backingbacking layer.

The disadvantage of the existing first method for measuring the thickness of the silicon epitaxial layer is that it requires the silicon epitaxial layer grown in a Si epitaxy equipment having a Ge source. However, in the manufacturing production line for semiconductor integrated circuits, in many cases, the Si epitaxy equipment is not provided with a Ge source so can only grow a Si epitaxial layer, not the SiGe epitaxial layer. Therefore, the application of the existing first method for measuring the thickness of the silicon epitaxial layer is limited.

Referring to FIGS. 3A-3B, which illustrate schematic structural diagrams of devices obtained in each step of an existing second method for measuring thickness of a silicon epitaxial layer. The existing second method for measuring the thickness of the silicon epitaxial layer includes the following steps:

Referring to FIG. 3A, forming a SiGe layer 302 on a surface of a silicon substrate 301 in SiGe epitaxy equipment.

Referring to FIG. 3B, a silicon substrate 301 pre-formed with a SiGe layer 302 on top is placed into a Si epitaxy equipment for epitaxial growth, a Si epitaxial layer 303 is grown on the SiGe layer 302.

Similarly, the thickness of the Si epitaxial layer 303 is measured by using the SiGe epitaxial layer 302 as a backing layer.

However, the existing second method for measuring the thickness of the silicon epitaxial layer has the following disadvantage:

In the Si epitaxy equipment, there are a pre-cleaning chamber and an epitaxial growth chamber. The silicon substrate 301 is first placed in the pre-cleaning chamber for dry chemical pre-cleaning, and the reactants in the cleaning chamber include NF₃ and NH₃. However, since the SiGe epitaxial layer 302 is already formed on the surface of the silicon substrate 301 as shown in FIG. 3B, the Ge in SiGe layer easily contaminates the pre-cleaning chamber.

### BRIEF SUMMARY

According to some embodiments in this application, a method for measuring the thickness of the silicon epitaxial layer is disclosed in the following steps:

step 1: providing a first wafer having a first silicon substrate, and performing epitaxial growth to grow a first semiconductor material layer on a surface of the first wafer, wherein a material of the first semiconductor material layer is optically distinguishable from a silicon film;

step 2: performing an epitaxial growth to grow a first silicon epitaxial layer on a surface of the first semiconductor material layer;

step 3: measuring a thickness of silicon by using the first semiconductor material layer as a backing layer to obtain a first thickness of the first silicon epitaxial layer:

step 4: performing epitaxial growth in a Si epitaxy equipment to form a second silicon epitaxial layer on a surface of the first silicon epitaxial layer, wherein the second silicon epitaxial layer is the silicon epitaxial layer; and

step 5: measuring a thickness of silicon by using the first semiconductor material layer as a backing layer to obtain a superposed thickness of the first silicon epitaxial layer and the second silicon epitaxial layer, and subtracting the first thickness from the superimposed thickness to obtain the thickness of the silicon epitaxial layer.

In some cases, the material of the first semiconductor material layer includes SiGe.

In some cases, in step 1, the first semiconductor material layer is grown in SiGe epitaxy equipment.

In some cases, in step 2, the first silicon epitaxial layer is grown in situ in the SiGe epitaxy equipment.

In some cases, the Si epitaxy equipment includes a pre-cleaning chamber and an epitaxial growth chamber:

before performing the epitaxial growth of the second silicon epitaxial layer, the method further includes a step of placing the first wafer into the pre-cleaning chamber for dry chemical pre-cleaning: during the dry chemical pre-cleaning, the first silicon epitaxial layer is used for covering the first semiconductor material layer and preventing Ge in the first semiconductor material layer from contaminating the pre-cleaning chamber.

In some cases, reactants for the dry chemical pre-cleaning include NF3 and NH3.

In some cases, the first wafer is a measurement wafer; in step 5, in a case that the second thickness meets a product requirement, epitaxial growth is directly performed on a second wafer composed of a second silicon substrate in the Si epitaxy equipment to form a third silicon epitaxial layer: epitaxial growth parameters for the third silicon epitaxial layer are the same as epitaxial growth parameters for the second silicon epitaxial layer, and the second wafer is a product wafer.

In some cases, in step 5, in a case that the second thickness does not meet the product requirement, the epitaxial growth parameters of the Si epitaxy equipment are adjusted, and step 1 to step 5 are repeated until the second thickness meets the product requirement.

In some cases, a well region is formed in a surface area of the second silicon substrate of the second wafer:

the third silicon epitaxial layer is used as a forming layer of a channel region of a semiconductor device.

In some cases, the semiconductor device includes NMOS and PMOS.

In some cases, in step 3, a plurality of points are selected on the first wafer to measure the first thickness: in step 5, a plurality of points are selected on the first wafer to measure the superposed thickness and obtain the second thickness at the plurality of points.

In the present application, by pre-growing the first semiconductor material layer and the first silicon epitaxial layer on the surface of the first wafer before the epitaxial growth of the second silicon epitaxial layer on the first wafer, the material of the first semiconductor material layer is optically distinguishable from a silicon film, so that both the first silicon epitaxial layer and the second silicon epitaxial layer can be optically separated from the first silicon substrate of the first wafer, thus sequentially achieving the measurement of the first thickness of the first silicon epitaxial layer and the superposed thickness of the first silicon epitaxial layer and the second silicon epitaxial layer. By subtracting the first thickness from the superposed thickness, the second thickness of the second silicon epitaxial layer can be obtained, thus finally achieving the measurement of the second thickness of the second silicon epitaxial layer. In addition, the first silicon epitaxial layer in the present application is not grown together with the second silicon epitaxial layer, so the first semiconductor material layer can be covered by the first silicon epitaxial layer before the first wafer enters the epitaxial growth equipment of the second silicon epitaxial layer. In this way, after the first wafer enters the epitaxial growth equipment, i.e., the Si epitaxy equipment, of the second silicon epitaxial layer, the first silicon epitaxial layer can prevent elements different from silicon in the first semiconductor material layer from diffusing into the epitaxial growth equipment of the second silicon epitaxial layer and thus prevent the epitaxial growth equipment of the second silicon epitaxial layer from being contaminated. Therefore, the present application can overcome the disadvantage that the silicon substrate is not optically distinguishable from the silicon epitaxial layer, thus achieving the accurate measurement of the silicon epitaxial layer without causing contamination to the Si epitaxy equipment.

### BRIEF DESCRIPTION OF THE DRAWINGS

The present application will be further described below in detail in combination with the specific embodiments with reference to the drawings.

FIGS. 1A-1C illustrate schematic structural diagrams of devices obtained in each step of an existing process for forming an SRW.

FIG. 2 illustrates a schematic structural diagram of a device obtained in an existing first method for measuring thickness of a silicon epitaxial layer.

FIGS. 3A-3B illustrate schematic structural diagrams of devices obtained in an existing second method for measuring thickness of a silicon epitaxial layer.

FIG. 4 illustrates a flowchart of a method for measuring thickness of a silicon epitaxial layer according to an embodiment of the present application.

FIGS. 5A-5C illustrate schematic structural diagrams of devices obtained in each step of a method for measuring thickness of a silicon epitaxial layer according to an embodiment of the present application.

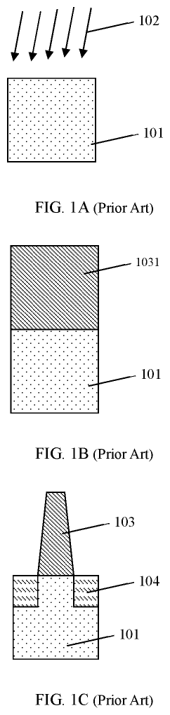

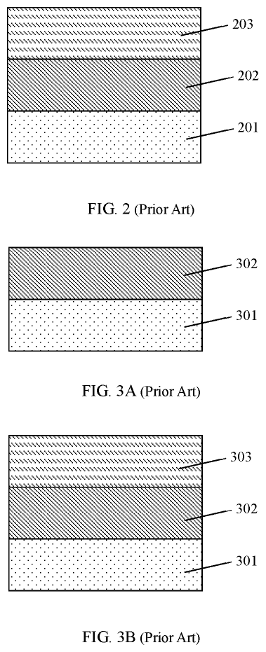

### DETAILED DESCRIPTION

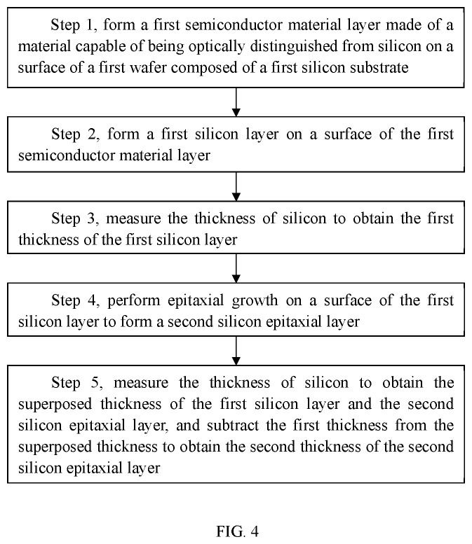

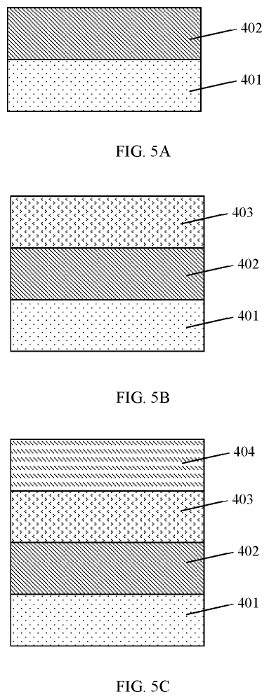

Referring to FIG. 4, it illustrates a flowchart of a method for measuring thickness of a silicon epitaxial layer according to an embodiment of the present application. Referring to FIGS. 5A-5C, which illustrate schematic structural diagrams of devices obtained in each step of a method for measuring thickness of a silicon epitaxial layer according to an embodiment of the present application. The method for measuring the thickness of the silicon epitaxial layer according to the embodiment of the present application includes the following steps:

In step 1, referring to FIG. 5, a first wafer 401 having a first silicon substrate is provided, and epitaxial growth is performed to grow a first semiconductor material layer 402 on a surface of the first wafer 401. The material of the first semiconductor material layer 402 is optically distinguishable from a silicon film.

In the embodiment of the present application, the material of the first semiconductor material layer 402 includes SiGe.

The first semiconductor material layer 402 is grown in SiGe epitaxy equipment.

In step 2, referring to FIG. 5B, epitaxial growth is performed to grow a first silicon epitaxial layer 403 on a surface of the first semiconductor material layer 402.

In the embodiment of the present application, the first silicon epitaxial layer 403 is grown in situ in the SiGe epitaxy equipment.

In step 3, the thickness of silicon is measured by using the first semiconductor material layer 402 as a backing layer to obtain the first thickness of the first silicon epitaxial layer 403.

In step 4, epitaxial growth is performed in Si epitaxy equipment to form a second silicon epitaxial layer 404 on a surface of the first silicon epitaxial layer 403.

In the embodiment of the present application, the Si epitaxy equipment includes a pre-cleaning chamber and an epitaxial growth chamber.

Before performing the epitaxial growth of the second silicon epitaxial layer 404, the method further includes a step of placing the first wafer 401 into the pre-cleaning chamber for dry chemical pre-cleaning: during the dry chemical pre-cleaning, the first silicon epitaxial layer 403 is used for covering the first semiconductor material layer 402 and preventing Ge in the first semiconductor material layer 402 from contaminating the pre-cleaning chamber.

In some embodiments, reactants for the dry chemical pre-cleaning include NF3 and NH3. The dry chemical pre-cleaning using reactants including NF3 and NH3 typically includes SiCoNi cleaning.

In step 5, the thickness of silicon is measured by using the first semiconductor material layer 402 as a backing layer to obtain the superposed thickness of the first silicon epitaxial layer 403 and the second silicon epitaxial layer 404, and the first thickness is subtracted from the superimposed thickness to obtain the second thickness of the second silicon epitaxial layer 404.

In the embodiment of the present application, the first wafer 401 is a measurement wafer: in step 5, in a case that the second thickness meets a product requirement, epitaxial growth is directly performed on a second wafer composed of a second silicon substrate in the Si epitaxy equipment to form a third silicon epitaxial layer: epitaxial growth parameters for the third silicon epitaxial layer are the same as epitaxial growth parameters for the second silicon epitaxial layer 404, and the second wafer is a product wafer.

Alternatively, in step 5, in a case that the second thickness does not meet the product requirement, the epitaxial growth parameters of the Si epitaxy equipment are adjusted, and step 1 to step 5 are repeated until the second thickness meets the product requirement.

A well region is formed in a surface area of the second silicon substrate of the second wafer.

The third silicon epitaxial layer is used as a forming layer of a channel region of a semiconductor device.

The semiconductor device includes NMOS and PMOS.

In the embodiment of the present application, in step 3, a plurality of points are selected on the first wafer to measure the first thickness: in step 5, a plurality of points are selected on the first wafer to measure the superposed thickness and obtain the second thickness at the plurality of points. By measuring the second thickness at the plurality of points, the thickness uniformity of the second silicon epitaxial layer 404 can be obtained.

In some embodiments, the thickness of the second silicon epitaxial layer 404 is 10 nm-100 nm.

In the embodiment of the present application, by pre-growing the first semiconductor material layer 402 and the first silicon epitaxial layer 403 on the surface of the first wafer 401 before the epitaxial growth of the second silicon epitaxial layer 404 on the first wafer 401, the material of the first semiconductor material layer 402 is optically distinguishable from a silicon film, so that both the first silicon epitaxial layer 403 and the second silicon epitaxial layer 404 can be optically separated from the first silicon substrate of the first wafer 401, thus sequentially achieving the measurement of the first thickness of the first silicon epitaxial layer 403 and the superposed thickness of the first silicon epitaxial layer 403 and the second silicon epitaxial layer 404. By subtracting the first thickness from the superposed thickness, the second thickness of the second silicon epitaxial layer 404 can be obtained, thus finally achieving the measurement of the second thickness of the second silicon epitaxial layer 404. In addition, the first silicon epitaxial layer 403 in the present application is not grown together with the second silicon epitaxial layer 404, so the first semiconductor material layer 402 can be covered by the first silicon epitaxial layer 403 before the first wafer 401 enters the epitaxial growth equipment of the second silicon epitaxial layer 404. In this way, after the first wafer 401 enters the epitaxial growth equipment, i.e., the Si epitaxy equipment, of the second silicon epitaxial layer 404, the first silicon epitaxial layer 403 can prevent elements different from silicon in the first semiconductor material layer 402 from diffusing into the epitaxial growth equipment of the second silicon epitaxial layer 404 and thus prevent the epitaxial growth equipment of the second silicon epitaxial layer 404 from being contaminated. Therefore, the embodiment of the present application can overcome the disadvantage that the silicon substrate is not optically distinguishable from the silicon epitaxial layer, thus achieving the accurate measurement of the silicon epitaxial layer without causing contamination to the Si epitaxy equipment.

The present application has been described above in detail through the specific embodiments, which, however, do not constitute limitations to the present application. Without departing from the principle of the present application, those skilled in the art may make many modifications and improvements, which should also be considered as included in the scope of protection of the present application.

What is claimed is:

1. A method for measuring a thickness of a silicon epitaxial layer, comprising following steps:
step 1: providing a first wafer having a first silicon substrate, and performing epitaxial growth to grow a first semiconductor material layer on a surface of the first wafer, wherein a material of the first semiconductor material layer is optically distinguishable from a silicon film;
step 2: performing an epitaxial growth to grow a first silicon epitaxial layer on a surface of the first semiconductor material layer;
step 3: measuring a thickness of silicon by using the first semiconductor material layer as a backing layer to obtain a first thickness of the first silicon epitaxial layer;
step 4: performing epitaxial growth in a Si epitaxy equipment to form a second silicon epitaxial layer on a surface of the first silicon epitaxial layer, wherein the second silicon epitaxial layer is the silicon epitaxial layer; and
step 5: measuring a thickness of silicon by using the first semiconductor material layer as a backing layer to obtain a superposed thickness of the first silicon epitaxial layer and the second silicon epitaxial layer, and subtracting the first thickness from the superimposed thickness to obtain the thickness of the silicon epitaxial layer.

2. The method for measuring the thickness of the silicon epitaxial layer according to claim 1, wherein the material of the first semiconductor material layer comprises SiGe.

3. The method for measuring the thickness of the silicon epitaxial layer according to claim 2, wherein in step 1, the first semiconductor material layer is grown in a SiGe epitaxy equipment and comprises Ge.

4. The method for measuring the thickness of the silicon epitaxial layer according to claim 3, wherein in step 2, the first silicon epitaxial layer is grown in situ in the SiGe epitaxy equipment.

5. The method for measuring the thickness of the silicon epitaxial layer according to claim 4, wherein in step 4, the Si epitaxy equipment comprises a pre-cleaning chamber and an epitaxial growth chamber:
wherein before performing the epitaxial growth of the second silicon epitaxial layer, the method further comprises a step of placing the first wafer into the pre-cleaning chamber for a dry chemical pre-cleaning, wherein during the dry chemical pre-cleaning, the first silicon epitaxial layer covers the first semiconductor material layer and prevents the Ge in the first semiconductor material layer from contaminating the pre-cleaning chamber.

6. The method for measuring the thickness of the silicon epitaxial layer according to claim 5, wherein reactants for the dry chemical pre-cleaning comprise NF₃ and NH₃.

7. The method for measuring the thickness of the silicon epitaxial layer according to claim 5, wherein the first wafer is a measurement wafer: wherein in step 5, in a case that the second thickness meets a product thickness requirement, an epitaxial growth is directly performed on a second wafer having a second silicon substrate in the Si epitaxy equipment to form a third silicon epitaxial layer on the second wafer, wherein epitaxial growth parameters for the third silicon epitaxial layer are same as epitaxial growth parameters for the second silicon epitaxial layer, and wherein the second wafer is a product wafer.

8. The method for measuring the thickness of the silicon epitaxial layer according to claim 7, wherein in step 5, in a case that the second thickness does not meet the product thickness requirement, the epitaxial growth parameters of the Si epitaxy equipment are adjusted, and the step 1 to the step 5 are repeated until the second thickness meets the product thickness requirement.

9. The method for measuring the thickness of the silicon epitaxial layer according to claim 7, wherein a well region is formed in a surface area of the second silicon substrate of the second wafer; and
wherein the third silicon epitaxial layer is a forming layer of a channel region of a semiconductor device.

10. The method for measuring the thickness of the silicon epitaxial layer according to claim 9, wherein the semiconductor device comprises NMOS and PMOS.

11. The method for measuring the thickness of the silicon epitaxial layer according to claim 1, wherein in step 3, a plurality of points are selected on the first wafer to measure the first thickness; and wherein in step 5, the plurality of points are selected on the first wafer to measure the superposed thickness and obtain the second thickness at the plurality of points.
